(19) United States
(12) Patent Application Publication
(10) Pub. No.: US 2008/0311512 A1
(43) Pub. Date: Dec. 18, 2008

(54) PHOTOSENSITIVE RESIN COMPOSITION AND METHOD FOR PATTERN FORMING

(75) Inventors: Takahiro Senzaki, Kawasaki-shi (JP); Atsushi Yamanouchi, Kawasaki-shi (JP); Junzo Yonekura, Kawasaki-shi (JP); Koji Saito, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Tokyo Ohka Kogyo Co., Ltd., Kawasaki-shi (JP)

(21) Appl. No.: 12/136,438

(22) Filed: Jun. 10, 2008

(30) Foreign Application Priority Data
Jun. 14, 2007 (JP) 2007-157316

(51) Int. Cl. G03F 7/004; G03F 7/20

(52) U.S. Cl. 430/280.1; 430/286.1; 430/322

(57) ABSTRACT

A photosensitive resin composition, which displays superior adhesion with substrates when forming a film and can form fine resin patterns with larger film thicknesses and higher aspect ratios, and a method for forming a pattern using the same are provided. Diphenyl sulfone or derivatives thereof are included into the photosensitive resin composition as an adhesion enhancer. Preferably, the diphenyl sulfone derivative is derived by substituting at least one hydrogen atom of diphenyl sulfone with an amino group, a nitro group, hydroxyl group, carboxyl group, fluorine atom, chlorine atom or acid anhydride.

### RELATED APPLICATION

This application claims priority under 35 U.S.C. § 119(a)-(d) to Japanese Patent Application No. 2007-157316, filed on Jun. 14, 2007, the content of which is incorporated herein by reference.

### BACKGROUND OF THE INVENTION

1. Field of the Invention

The present invention relates to a photosensitive resin composition and a method for forming a pattern using the same. More specifically, the present invention relates to a photosensitive resin composition that is favorably used for forming connecting terminals such as bumps and metal posts, wiring patterns and the like, in producing circuit substrates or producing electronics parts such as chip size packages (CSP) mounted on circuit substrates, micro electronics machine system (MEMS) elements and micro machines incorporating the MEMS elements and penetrating electrodes for high density packaging, as well as a method for forming a pattern using the same.

2. Related Art

Photofabrication, which is now the mainstream of a microfabrication technique, is a generic term describing the technology used for manufacturing a wide variety of precision components, such as semiconductor packages and MS elements. The manufacturing is carried out by applying a photosensitive resin composition to the surface of a processing target to form a coating, patterning this coating using photolithographic techniques, and then conducting electroforming based mainly on chemical etching or electrolytic etching, and/or electroplating, using the patterned coating as a mask.

In recent years, high density packaging technologies have progressed in semiconductor packages along with downsizing electronics devices, and the increase in package density has been developed on the basis of mounting multi-pin thin film in packages, miniaturizing of package size, two-dimensional packaging technologies in flip-tip systems or three-dimensional packaging technologies. In these types of high density packaging techniques, connection terminals, including protruding electrodes (mounting terminals) known as bumps that protrude above the package or metal posts that extend from peripheral terminals on the wafer and connect rewiring with the mounting terminals, are disposed on the surface of the substrate with high precision.

The materials used in the photofabrication described above are typically photosensitive resin compositions for thick film. The photosensitive resin compositions are employed for forming thick photoresist layers and are used, for example, to form bumps or metal posts in plating processes. Bumps or metal posts can be formed, for example, by forming a thick resist layer of about 20 μm thick on a support, exposing the resist layer through a predetermined mask pattern, developing the layer to form a resist pattern in which the portions for forming the bumps or metal posts are selectively removed (stripped), embedding a conductor such as copper into the stripped portions (resist-free portions) using plating, and then removing the surrounding residual resist pattern.

In regards to the photosensitive resin compositions for a thick film, a positive-type photosensitive resin composition, employed for forming bumps or wirings, is disclosed that contains a quinone diazide group-containing compound (see Japanese Unexamined Patent Application Publication No. 2002-258479).

On the other hand, photosensitive resin compositions of chemical amplification type containing an acid generator are publicly known as a photosensitive resin composition that is more sensitive than conventional photosensitive resin compositions that contain a quinone diazide group-containing compound. The photosensitive resin compositions of chemical amplification type are characterized in that an acid is generated from the acid generator upon being irradiated with a radiation ray (exposure) and diffusion of the acid is promoted through heat treatment after the exposure to cause an acid catalytic reaction with a base resin in the resin composition to change its alkali-solubility.

The photosensitive resin compositions of chemical amplification type are classified into: positive type in which their alkali-insolubility turns into alkali-solubility; and negative type in which their alkali-solubility turns into alkali-insolubility upon being irradiated with the radiation ray. In regards to the positive type among these, for example, a photosensitive resin composition is disclosed that contains a resin having a repeating unit with an acid-dissociative functional group such as t-butyl(meth)acrylate and an acid generator such as onium salt compounds (see Japanese Unexamined Patent Application Publication No. 2001-281862). In addition, in regards to the negative type among these, for example, a photosensitive resin composition is disclosed that contains an epoxy-functional novolac resin, an acid generator such as triaryl sulfonium salts, and a dilution agent capable of reacting with an epoxy-reactive group. (see Japanese Examined Patent Application Publication No. H07-78628)

### SUMMARY OF THE INVENTION

Incidentally, there has been a problem such that conventional photosensitive resin compositions of chemical amplification type display insufficient adhesion with substrates when forming a film. Silane coupling agents have been thus far known as an adhesion enhancer to improve adhesion with substrates; however, negative-type photosensitive resin compositions, which contain epoxy resins in particular, suffer from very poor adhesion with substrates such as of gold and copper, and thus it has been difficult to form fine resin patterns with larger film thicknesses and higher aspect ratios, even when adding silane coupling agents.

The present invention has been made in view of the problems described above; it is an object of the present invention to provide a photosensitive resin composition that displays excellent adhesion with substrates when forming a film and can form fine resin patterns with larger film thicknesses and higher aspect ratios, and also to provide a method for forming a pattern using the same.

The present inventors have thoroughly investigated to attain the object described above, and as a result have found that the problems described above can be solved by way of incorporating a specific compound into the photosensitive resin composition, thereby completing the present invention. Specifically, the present invention provides the following.

In a first aspect of the present invention, a photosensitive resin composition contains diphenyl sulfone or a derivative thereof as an adhesion enhancer.

In a second aspect of the present invention, a method for forming a pattern is provided wherein a photosensitive resin composition according to the present invention is coated and dried on a substrate to form a coating, and the coating is exposed with a predetermined pattern, and developed to prepare a resin pattern with a predetermined shape.

In accordance with the photosensitive resin composition of the present invention, fine resin patterns can be formed with larger film thicknesses and higher aspect ratios by virtue of superior adhesion with substrates when forming a film.

### DETAILED DESCRIPTION OF THE INVENTION

### Photosensitive Resin Composition

The photosensitive resin composition of the present invention is characterized in containing diphenyl sulfone or a derivative thereof as an adhesion enhancer. The photosensitive resin composition may be either of a negative or positive type. Each component, contained in the photosensitive resin composition, will be explained in the following.

### Negative-Type Photosensitive Resin Composition

It is preferred that the negative-type photosensitive resin composition contains a polyfunctional epoxy resin (A), an acid generator to generate an acid upon being irradiated with an active light ray or radiation (B) and an adhesion enhancer (C) as essential components, and also an optional polymer of linear bifunctional epoxy resin (D), etc., and it is preferred that these components are used in a solution condition through dissolving these components into a solvent (E). When the polyfunctional epoxy resin (A) and the acid generator (B) are used in combination, exposed portions become alkali-insoluble since the portions undergo cation polymerization by action of an acid generated at the portions, and thus unexposed portions are selectively removed upon development to produce a predetermined resin pattern.

### Polyfunctional Epoxy Resin (A)

The negative-type photosensitive resin composition contains a polyfunctional epoxy resin (A) (hereinafter, appropriately referred to as “component (A)”) as a base resin. It is preferred that the component (A), which is not limited specifically, has sufficient epoxy groups per molecule so as to form a resin pattern of a thick film. Examples of the component (A) include polyfunctional phenol novolac type epoxy resins, polyfunctional orthocresol novolac type epoxy resins, polyfunctional triphenyl type novolac type epoxy resins and polyfunctional bisphenol A novolac type epoxy resins. Among these, polyfunctional bisphenol A novolac type epoxy resins are preferably used. Preferably, the functionality is at least five; commercially available examples thereof are “jER157S70” (by Japan Epoxy Resins Co., Ltd.) and “Epichron N-885” (by Dainippon Ink & Chemicals, Inc.), which are preferably used in particular.

The polyfunctional bisphenol A novolac type epoxy resins described above are expressed by the general formula (a1) below:

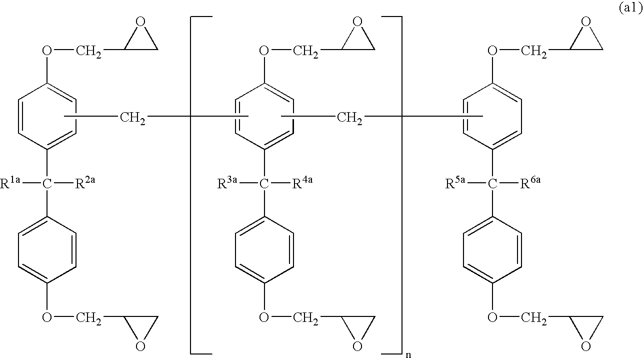

In the general formula (a1) above, R^{1a} to R^{6a} each represents a hydrogen atom or a methyl group; “n” is a repeating unit. The epoxy group in the bisphenol A novolac type epoxy resin, expressed by the general formula (a1) above, may be a polymer that is polymerized with a bisphenol A type epoxy resin or a bisphenol A novolac type epoxy resin.

Preferably, the content of the component (A) is 80% to 99.9% by mass based on the solid content of the negative-type photosensitive resin composition, and more preferably 92% to 99.4% by mass. Consequently, the resin pattern may be provided with higher sensitivity and appropriate hardness.

### Acid Generator (B)

The negative-type photosensitive resin composition contains an acid generator (B) that generates an acid upon being irradiated with an active light ray or radiation (hereinafter, appropriately referred to as “component (B)”). The acid, generated from the acid generator (B), catalyzes the polymerization reaction of the polyfunctional epoxy resin (A).

Examples of the component (B) in the first aspect include halogen-containing triazine compounds such as 2,4-bis(trichloromethyl)-6-piperonyl-1,3,5-triazine, 2,4-bis(trichloromethyl)-6-[2-(2-furyl)ethenyl]-s-triazine, 2,4-bis(trichloromethyl)-6-[2-(5-methyl-2-furyl)ethenyl]-s-triazine, 2,4-bis(trichloromethyl)-6-[2-(5-ethyl-2-furyl)ethenyl]-s-triazine, 2,4-bis(trichloromethyl)-6-[2-(5-propyl-2-furyl)ethenyl]-s-triazine, 2,4-bis(trichloromethyl)-6-[2-(3,5-dimethoxyphenyl)ethenyl]-s-triazine, 2,4-bis(trichloromethyl)-6-[2-(3,5-diethoxyphenyl)ethenyl]-s-triazine, 2,4-bis(trichloromethyl)-6-[2-(3,5-dipropoxyphenyl)ethenyl]-s-triazine, 2,4-bis(trichloromethyl)-6-[2-(3-methoxy-5-ethoxyphenyl)ethenyl]-s-triazine, 2,4-bis(trichloromethyl)-6-[2-(3-methoxy-5-propoxyphenyl)ethenyl]-s-triazine, 2,4-bis(trichloromethyl)-6-[2-(3,4-methylenedioxyphenyl)ethenyl]-s-triazine, 2,4-bis(trichloromethyl)-6-(3,4-methylenedioxyphenyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(2-bromo-4-methoxy)styrylphenyl-s-triazine, 2,4-bis-trichloromethyl-6-(3-bromo-4-methoxy)styrylphenyl-s-triazine, 2-(4-methoxyphenyl)-4,6-bis(trichloromethyl)-1,3,5-triazine, 2-(4-methoxynaphthyl)-4,6-bis(trichloromethyl)-1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethyl)-1,3,5-triazine, 2-[2-(3,5-dimethoxyphenyl)ethenyl]-4,6-bis(trichloromethyl)-1,3,5-triazine, 2-[2-(3,4-dimethoxyphenyl)ethenyl]-4,6-bis(trichloromethyl)-1,3,5-triazine, 2-(3,4-methylenedioxyphenyl)-4,6-bis(trichloromethyl)-1,3,5-triazine, tris(1,3-dibromopropyl)-1,3,5-triazine, and tris(2,3-dibromopropyl)-1,3,5-triazine, and halogen-containing triazine compounds, expressed by the general formula (b1) below, such as tris(2,3-dibromopropyl)isocyanurate.

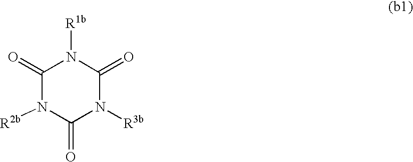

In the general formula (b1) above, R^{1b} to R^{3b} each independently represents a halogenated alkyl group, and the alkyl group has 1 to 6 carbon atoms.

In addition, examples of the component (B) in the second aspect include α-(p-toluenesulfonyloxyimino)-phenylacetonitrile, α-(benzenesulfonyloxyimino)-2,4-dichlorophenylacetonitrile, α-(benzenesulfonyloxyimino)-2,6-dichlorophenylacetonitrile, α-(2-chlorobenzenesulfonyloxyimino)-4-methoxyphenylacetonitrile, α-(ethylsulfonyloxyimino)-1-cyclopentenylacetonitrile, and compounds containing an oximesulfonate group expressed by the general formula (b2) below.

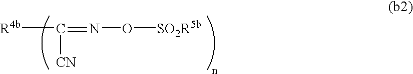

In the general formula (b2) above, R^{4b} represents a mono-, di- or trivalent organic group; R^{5b} represents a substituted or unsubstituted, saturated or unsaturated hydrocarbon group or an aromatic compound group; n is an integer of 1 to 6.

It is particularly preferable that R^{4b} in the general formula (b2) above is an aromatic compound group; examples of the aromatic compound group include aromatic hydrocarbon groups such as a phenyl group and a naphthyl group, and heterocyclic groups such as a furyl group and thienyl group. These may have one or more appropriate substituents such as halogen atoms, alkyl groups, alkoxy groups and nitro groups on the rings. It is also particularly preferable that R^{5b} is a lower alkyl group having 1 to 6 carbon atoms such as a methyl group, ethyl group, propyl group and butyl group.

Examples of an acid generator represented by the general formula (b2) above include compounds in which R^{4b} is a phenyl group, a methylphenyl group or a methoxyphenyl group and R^{5b} is a methyl group, when n=1, and specific examples thereof include α-(methylsulfonyloxyimino)-1-phenylacetonitrile, α-(methylsulfonyloxyimino)-1-(p-methylphenyl)acetonitrile, α-(methylsulfonyloxyimino)-1-(p-methoxyphenyl)acetonitrile, [2-(propylsulfonyloxyimino)-2,3-dihydroxythiophene-3-ylidene](o-tolyl)acetonitrile or the like. When n=2, the acid generator expressed by the general formula (b2) above is specifically one expressed by the chemical formulas (b2-1) to (b2-8) below.

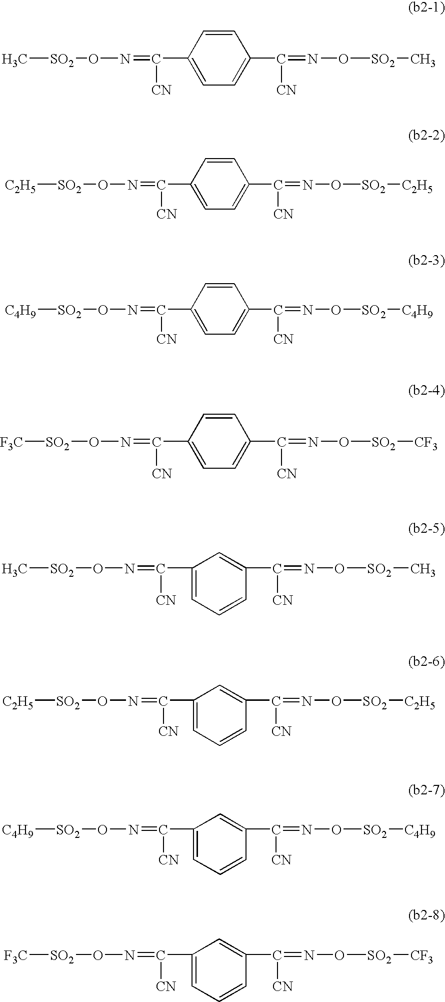

In addition, examples of the component (B) in the third aspect are onium salts that have a naphthalene ring at their cation portions. The expression “have a naphthalene ring” indicates having a structure derived from naphthalene and also indicates having at least a two-ring structure and to maintain their aromatic properties. The naphthalene ring may have a substituent of linear or branched alkyl groups having 1 to 6 carbon atoms, a hydroxyl group, linear or branched alkoxy groups having 1 to 6 carbon atoms, or the like. The structure derived from the naphthalene ring, which may be of a monovalent group (one free valance) or of a divalent group (two free valences), is desirably of a monovalent group (in this regard, the number of free valance is counted except for the portions connecting with the substituents described above). The number of naphthalene rings is preferably 1 to 3.

Preferably, the cation portion of onium salts having a naphthalene ring at the cation portion is of the structure expressed by the general formula (b3) below.

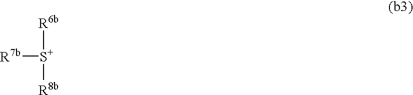

In the general formula (b3) above, at least one of R^{6b} to R^{8b} is a group expressed by the general formula (b4) below, and the remaining is a linear or branched alkyl group having 1 to 6 carbon atoms, a hydroxyl group, or a linear or branched alkoxy group having 1 to 6 carbon atoms. Alternatively, one of R^{6b} to R^{8b} is a group expressed by the general formula (b4) below, and the remaining two are each independently a linear or branched alkylene group having 1 to 6 carbon atoms, and these terminals may bond to form a ring structure.

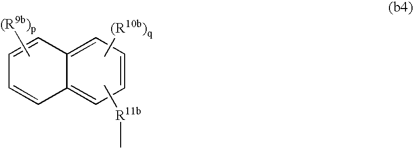

In the general formula (b4) above, R^{9b} and R^{10b} each independently represents a hydroxyl group, a linear or branched alkoxy group having 1 to 6 carbon atoms, or a linear or branched alkyl group having 1 to 6 carbon atoms; R^{11b} represents a single bond or a linear or branched alkylene group having 1 to 6 carbon atoms that may have a substituent; p and q are each independently an integer of 0 to 2; p+q is no greater than 3. In this regard, when there exist a plurality of R^{10b}s, they may be identical or different from each other. Furthermore, when there exist a plurality of R^{9b}s, they may be identical or different from each other.

Preferably, the number of groups, expressed by the general formula (b4) above, among R^{6b} to R^{8b}, is one and the remaining is linear or branched alkylene groups having 1 to 6 carbon atoms of which the terminals may bond to form a ring. In this case, the two alkylene groups described above form a 3 to 9 membered ring including sulfur atom(s). Preferably, the number of atoms to form the ring (including sulfur atom(s)) is 5 or 6.

The substituent, which the alkylene group may have, is exemplified by an oxygen atom (in this case, a carbonyl group is formed together with a carbon atom to constitute the alkylene group), a hydroxyl group or the like.

The substituent, which the phenyl group may have, is exemplified by a hydroxyl group, linear or branched alkoxy groups having 1 to 6 carbon atoms, linear or branched alkyl groups having 1 to 6 carbon atoms or the like.

These cation portions are preferably those expressed by the chemical formulas (b5) and (b6) below, and the structure expressed by the chemical formula (b6) is particularly preferable.

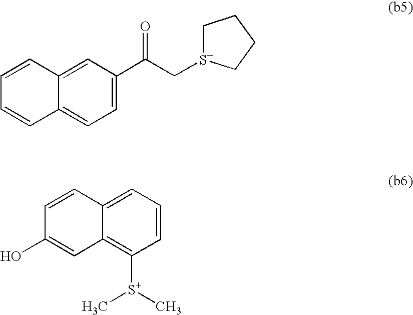

The cation portions, which may be of an iodonium salt or sulfonium salt, are desirably of a sulfonium salt in view of acid-generating efficiency.

It is, therefore, desirable that the preferable anion portion of the onium salt, having a naphthalene ring at the cation portion, is an anion capable of forming a sulfonium salt.

The anion portion of the acid generator is exemplified by fluoroalkylsulfonic acid ions, of which hydrogen atom(s) being partially or entirely fluorinated, or aryl sulfonic acid ions.

The alkyl group of the fluoroalkylsulfonic acid ions may be linear, branched or cyclic and have 1 to 20 carbon atoms; preferably, the carbon number is 1 to 10 in view of bulkiness and diffusion distance of the generating acid. In particular, branched or cyclic ones are preferable due to shorter diffusion length. Specifically, methyl, ethyl, propyl, butyl, octyl groups and the like are preferable due to being inexpensively synthesizable.

The aryl group of the aryl sulfonic acid ions may be an aryl group having 6 to 20 carbon atoms, and is exemplified by a phenol group or a naphthyl group that may be substituted or unsubstituted with alkyl groups or halogen atoms; preferably, the aryl group is one having 6 to 10 carbon atoms since these can be synthesized inexpensively. Specifically, phenyl, toluene sulfonyl, ethylphenyl, naphthyl, methylnaphtyl groups and the like are preferable.

When the hydrogen atom is partially or entirely fluorinated in the fluoroalkylsulfonic acid ions or aryl sulfonic acid ions, the fluorination rate is preferably 10% to 100%, and more preferably 50% to 100%; it is particularly preferable that all of hydrogen atoms are substituted with fluorine atoms in view of higher acid strength. Specific examples thereof include trifluoromethane sulfonate, perfluorobutane sulfonate, perfluorooctane sulfonate and perfluorobenzene sulfonate.

Among others, the preferable anion portion is exemplified by those expressed by the general formula (b7) below.

R^{12b}SO₃— (b7)

In the general formula (b7) above, R^{12b} represents a structure expressed by the general formula (b8) or (b9) below or the chemical formula (b10).

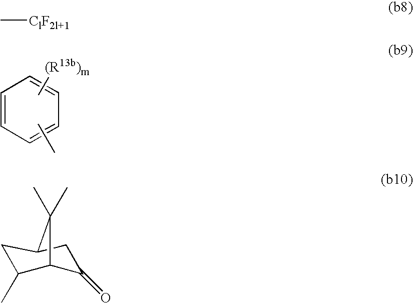

In the general formula (b8) above, l is an integer of 1 to 4; R^{13b} in the general formula (b9) is a hydrogen atom, a hydroxyl group, a linear or branched alkyl group having 1 to 6 carbon atoms or a linear or branched alkoxy group having 1 to 6 carbon atoms; and m is an integer of 1 to 3. Among others, trifluoromethane sulfonate and perfluorobutane sulfonate are preferable in view of safety.

In addition, nitrogen-containing ones expressed by the general formula (b11) or (b12) below may be used for the anion portion.

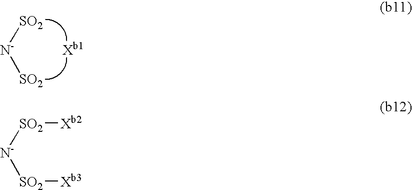

In the general formulas (b11) and (b12) above, X^{b1} represents a linear or branched alkylene group of which at least one hydrogen atom is substituted with a fluorine atom, the carbon number of the alkylene group is 2 to 6, preferably 3 to 5, and most preferably the carbon number is 3. In addition, X^{b2} and X^{b3} each independently represents a linear or branched alkyl group of which at least one hydrogen atom is substituted with a fluorine atom, the carbon number of the alkyl group is 1 to 10, preferably 1 to 7, and more preferably 1 to 3.

The smaller the carbon number of the alkylene group of X^{b1} or the carbon number of the alkyl group of X^{b2} or X^{b3} is, the more preferable and proper the solubility into resist solvent becomes.

In addition, larger number of hydrogen atoms substituted by fluorine atoms in X^{b1} of the alkylene group or in X^{b2} or X^{b3} of the alkyl group is preferred since the acid strength becomes stronger. The percentage of fluorine atoms in the alkylene or alkyl group, i.e. the fluorination rate, is preferably 70% to 100%, and more preferably 90% to 100%, and most preferable are perfluoroalkylene or perfluoroalkyl groups in which all of the hydrogen atoms are substituted with fluorine atoms.

Preferable onium salts having a naphthalene ring at their cation portions are exemplified by the compounds expressed by the chemical formula (b13) or (b14) below.

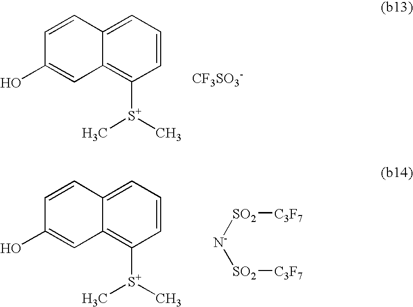

Examples of the component (B) in another aspect are bissulfonyldiazomethanes such as bis(p-toluenesulfonyl)diazomethane, bis(1,1-dimethylethylsulfonyl)diazomethane, bis(cyclohexylsulfonyl)diazomethane and bis(2,4-dimethylphenylsulfonyl)diazomethane; nitrobenzyl derivatives such as 2-nitrobenzyl p-toluenesulfonate, 2,6-dinitrobenzyl p-toluenesulfonate, nitrobenzyl tosylate, dinitrobenzyl tosylate, nitrobenzyl sulfonate, nitrobenzyl carbonate and dinitrobenzyl carbonate; sulfonates such as pyrogalloltrimesylate, pyrogalloltritosylate, benzyltosylate, benzylsulfonate, N-methylsulfonyloxy succinimide, N-trichloromethylsulfonyloxy succinimide, N-phenylsulfonyloxy maleimide and N-methylsulfonyloxy phthalimide; trifluoromethane sulfonates such as N-hydroxyphthalimide and N-hydroxynaphthalimide; onium salts such as diphenyliodonium hexafluorophosphate, (4-methoxyphenyl)phenyliodonium trifluoromethanesulfonate, bis(p-tert-butylphenyl)iodonium trifluoromethanesulfonate, triphenylsulfonium hexafluorophosphate, (4-methoxyphenyl)diphenylsulfonium trifluoromethanesulfonate, (p-tert-butylphenyl)diphenylsulfonium trifluoromethanesulfonate and diphenyl[4-(phenylthio)phenyl]sulfonium hexafluoroantimonate; benzointosylates such as benzointosylate and α-methylbenzointosylate; other diphenyliodonium salts, triphenylsulfonium salts, phenyldiazonium salts, benzylcarbonates and the like.

In addition, examples of the component (B) in the fourth aspect are the compounds expressed by the general formula (b15) below.

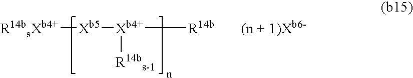

In the general formula (b15) above, X^{b4} represents a sulfur or iodine atom with an atomic valence of s, where s is 1 or 2. n is the number of repeating units. R^{14b}, which is an organic group bonding to X^{b4}, represents an aryl group having 6 to 30 carbon atoms, a heterocyclic group having 4 to 30 carbon atoms, an alkyl group having 1 to 30 carbon atoms, an alkenyl group having 2 to 30 carbon atoms, or an alkynyl group having 2 to 30 carbon atoms; R^{14b} may be substituted with at least one selected from the group consisting of alkyl, hydroxyl, alkoxy, alkylcarbonyl, arylcarbonyl, alkoxycarbonyl, aryloxycarbonyl, arylthiocarbonyl, acyloxy, arylthio, alkylthio, aryl, heterocyclic, aryloxy, alkylsulfinyl, arylsulfinyl, alkylsulfonyl, arylsulfonyl, alkyleneoxy, amino, cyano and nitro groups, and halogens. The number of R^{14b} is s+n(s−1)+1; a plurality of R¹⁴ as may be identical or different from each other. In addition, two or more R^{14b}s may bond directly or through —O—, —S—, —SO—, —SO₂—, —NH—, —NR^{15a}—, —CO—, —COO—, —CONH—, an alkylene group having 1 to 3 carbon atoms, or a phenylene group to form a ring structure containing X^{b4}. R^{15b} is an alkyl group having 1 to 5 carbon atoms or an aryl group having 6 to 10 carbon atoms.

X^{b5} is a structure expressed by the general formula (b16) below.

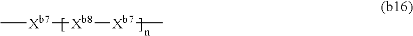

In the general formula (b16) above, X^{b7} represents an alkylene group having 1 to 8 carbon atoms, an arylene group having 6 to 20 carbon atoms or a divalent group of a heterocyclic compound having 8 to 20 carbon atoms; X^{b7} may be substituted with at least one selected from the group consisting of alkyl groups having 1 to 8 carbon atoms, alkoxy groups having 1 to 8 carbon atoms, aryl groups having 6 to 10 carbon atoms, hydroxyl, cyano, and nitro groups, and halogens. X^{b8} represents —O—, —S—, —SO—, —SO₂—, —NH—, —NR^{15b}—, —CO—, —COO—, —CONH—, an alkylene group having 1 to 3 carbon atoms or a phenylene group. n is the number of repeating units. X^{b7}s of n+1 and X^{b8}s of n may be identical or different from each other, respectively. The definition of R^{15b} is the same as that described above. X^{b6} is a counter ion of an onium. The number thereof is n+1 per molecule, and at least one thereof may be an anion of fluorinated alkylfluorophosphoric acid expressed by the general formula (b17) below, and the remaining may be other anions.

[(R^{16b})ₜPF₆₋ₜ] (b17)

In the general formula (b17) above, R^{16b} represents an alkyl group of which at least 80% of the hydrogen atoms are substituted with fluorine atoms. t represents the number thereof and is an integer of 1 to 5. R^{16b}s in the number of t may be identical or different from each other.

Preferable specific examples of onium ions expressed by the general formula (b15) above include triphenylsulfonium, tri-p-tolylsulfonium, 4-(phenylthio)phenyl diphenylsulfonium, bis[4-(diphenylsulfonio)phenyl]sulfide, bis[4-{bis[4-(2-hydroxyethoxy)phenyl]sulfonio}phenyl]sulfide, bis{4-[bis(4-fluorophenyl)sulfonio]phenyl}sulfide, 4-(4-benzoyl-2-chlorophenylthio)phenyl bis(4-fluorophenyl)sulfonium, 4-(4-benzoylphenylthio)phenyl diphenylsulfonium, 7-isopropyl-9-oxo-10-thia-9,10-dihydroanthracene-2-yldi-p-tolylsulfonium, 7-isopropyl-9-oxo-10-thia-9,10-dihydroanthracene-2-yldiphenylsulfonium, 2-[(diphenyl)sulfonio]thioxanthone, 4-[4-(4-tert-butylbenzoyl)phenylthio]phenyldi-p-totylsulfonium, 4-(4-benzoylphenylthio)phenyl diphenylsulfonium, diphenylphenacyl sulfonium, 4-hydroxyphenylmethylbenzylsulfonium, 2-naphthylmethyl(1-ethoxycarbonyl)ethylsulfonium, 4-hydroxyphenylmethylphenacyl sulfonium, octadecylmethylphenacyl sulfonium, diphenyliodonium, di-p-tolyliodonium, bis(4-dodecylphenyl)iodonium, bis(4-methoxyphenyl)iodonium, (4-octyloxyphenyl)phenyliodonium, bis(4-decyloxy)phenyliodonium, 4-(2-hydroxytetradecyloxy)phenyliodonium, 4-isopropylphenyl(p-tolyl)iodonium or 4-isobutylphenyl(p-tolyl)iodonium.

At least one fluorinated alkylfluorophosphoric acid expressed by the general formula (b17) above is the anion component(s) of the general formula (b15) above. The other anion components are other anions. The other anions, not limited specifically, may be conventional anions. Examples thereof include halogen ions such as F⁻, Cr⁻, Br⁻ and I⁻; OH⁻; ClO₄⁻; sulfonic acid ions such as FSO₃⁻, ClSO₃⁻, CH₃SO₃⁻, C₆H₅SO₃⁻ and CF₃SO₃⁻; sulfuric acid ions such as HSO₄⁻ and SO₄²⁻; carbonic acid ions such as HCO₃⁻ and CO₃²⁻; phosphoric acid ions such as H₂PO₄—, HPO₄²⁻ and PO₄³⁻; fluorophosphoric acid ions such as PF₆⁻ and PF₅OH⁻; boric acid ions such as BF₄⁻, B(C₆F₅)₄⁻ and B(C₆H₄CF₃)₄⁻; AlCl₄⁻; BiF₆⁻ and the like. Other examples are fluoroantimonic acid ions such as SbF₆⁻ and SbF₅OH⁻; and fluoroarsenic acid ions such as AsF₆⁻ and AsF₅OH⁻.

In regards to the anions of fluorinated alkylfluorophosphoric acid expressed by the general formula (b17) above, R^{16b} represents an alkyl group substituted with fluorine atoms, preferably having a carbon number of 1 to 8, and more preferably a carbon number of 1 to 4. Specific examples of the alkyl group include linear alkyl groups such as of methyl, ethyl, propyl, butyl, pentyl and octyl; branched alkyl groups such as of isopropyl, isobutyl, sec-butyl and tert-butyl; and cycloalkyl groups such as of cyclopropyl, cyclobutyl, cyclopentyl and cyclohexyl; the rate of hydrogen atoms in alkyl groups substituted with fluorine atoms is usually at least 80%, preferably at least 90%, and more preferably 100%. When the substitutional rate of fluorine atoms is below 80%, the acid strength of the onium fluorinated alkylfluorophosphate expressed by the general formula (a15) above tends to be low.

Particularly preferable R^{16b} is linear or branched perfluoroalkyl groups having 1 to 4 carbon atoms and a substitutional rate of fluorine atoms of 100%; specific examples thereof include CF₃, CF₃CF₂, (CF₃)₂CF, CF₃CF₂CF₂, CF₃CF₂CF₂CF₂, (CF₃)₂CFCF₂, CF₃CF₂(CF₃)CF and (CF₃)₃C. The number t of R^{16b}(s) is an integer of 1 to 5, preferably 2 to 4, and particularly preferably 2 or 3.

Specific examples of preferable anions of fluorinated alkylfluorophosphoric acid are [(CF₃CF₂)₂ PF₄]⁻, [(CF₃CF₂)₃ PF₃]⁻, [((CF₃)₂CF)₂ PF₄]⁻, [((CF₃)₂CF)₃ PF₃]⁻, [(CF₃CF₂CF₂)₂ PF₄]⁻, [(CF₃CF₂CF₂)₃ PF₃]⁻, [((CF₃)₂CFCF₂)₂ PF₄]⁻, [((CF₃)₂CFCF₂)₃ PF₃]⁻, [(CF₃CF₂CF₂CF₂)₂ PF₄]⁻ and [(CF₃CF₂CF₂)₃ PF₃]⁻; among these, [(CF₃CF₂)₃ PF₃]⁻, [(CF₃CF₂CF₂)₃ PF₃]⁻, [((CF₃)₂CF)₃ PF₃]⁻, [((CF₃)₂CF)₂ PF₄], [((CF₃)₂CFCF₂)₃ PF₃]⁻ and [((CF₃)₂CFCF₂)₂ PF₄]⁻ are particularly preferable.

Among the onium fluorinated alkylfluorophosphates expressed by the general formula (b15) above, diphenyl[4-(phenylthio)phenyl]sulfonium trifluorotrisfluoroalkylphosphate expressed by the general formula (b18) below is particularly preferably used.

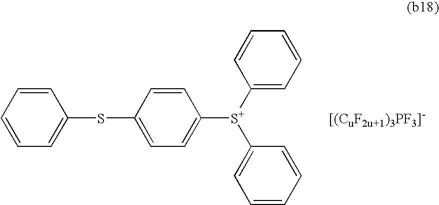

In the general formula (b18) above, u is an integer of 1 to 8, and preferably an integer of 1 to 4.

Preferably, at least one selected from the general formulas (b2) and (b18) is used as the component (B); in the general formula (b2), the preferable number of n is 2, preferable R^{4b} is divalent substituted or unsubstituted alkylene groups having 1 to 8 carbon atoms or substituted or unsubstituted aromatic groups, and preferable R^{5b} is substituted or unsubstituted alkyl groups having 1 to 8 carbon atoms or substituted or unsubstituted aryl groups.

The component (B) described above may be used alone or in combinations of two or more.

Preferably, the content of the component (B) is 0.5 to 20 parts by mass based on 100 parts of the (A) component. The content of the component (B) of 0.5 parts by mass or more may result in sufficient sensitivity, and the content of 20 parts by mass or less tends to enhance solubility in a solvent to provide a uniform solution and to improve preservation stability.

### Adhesion Enhancer (C)

The negative-type photosensitive resin composition contains diphenyl sulfone or a derivative thereof as an adhesion enhancer (C) (hereinafter, appropriately referred to as “component (C)”) to enhance adhesion with substrates when being formed into a film. Preferably, the derivative of diphenyl sulfone is one where one or more of hydrogen atoms of the diphenyl sulfone are substituted with amino groups, nitro groups, hydroxyl groups, carboxyl groups, fluorine atoms, chlorine atoms or acid anhydrides. It is preferred in particular that hydrogen atoms at 3,3′ positions and/or 4,4′ positions of the diphenyl sulfone are substituted with

amino groups, nitro groups, hydroxyl groups, carboxyl groups, fluorine atoms, chlorine atoms or acid anhydrides. The diphenyl sulfone derivative, substituted by an acid anhydride, is exemplified by 3,3′,4,4′-diphenylsulfone tetracarboxylic acid dianhydride.

Preferably, the content of component (C) is 0.01 to 20 parts by mass based on 100 parts by mass of the component (A), and more preferably 0.1 to 10 parts by mass. However, when the component (C) has an amino group or a nitro group, these functional groups deactivate the acid generated from the component (B), and it is, therefore, preferred that the content of component (C) is 0.01 to 20 parts by mass based on 100 parts by mass of the component (A), and more preferably 0.01 to 2 parts by mass. This can enhance adhesion with substrates when being formed into a film.

The diphenyl sulfone or derivatives thereof can enhance adhesion with substrates without depending on the species of base resins, and the adhesion enhancing effect is particularly significant in cases where an epoxy resin such as polyfunctional epoxy resin (A) is used as the base resin. The negative-type photosensitive resin composition, containing epoxy resin, displays very poor adhesion with substrates such as of gold and copper; however, when diphenyl sulfone or derivatives thereof are included as the component (C), fine resin patterns can be formed with larger film thicknesses and higher aspect ratios, even on gold or copper substrates.

### Linear Polymer Bifunctional Epoxy Resin (D)

The negative-type photosensitive resin composition may contain a linear polymer bifunctional epoxy resin (D) (hereinafter, appropriately referred to as “component (D)”) in order to improve film-forming ability. The component (D) is specifically a polymer of bisphenol A-type epoxy or bisphenol F-type epoxy; preferably, the mass average molecular mass is 2,000 to 7,000, and more preferably 3,000 to 5,000. The mass average molecular mass of no less than 1,000 can bring about proper film-forming ability and the molecular mass of no higher than 7,000 can lead to maintaining compatibility with the component (A). Preferably, Epicoat 1009 (by Japan Epoxy Resin Co., mass average molecular mass: 3,750) is used, for example, as the component (D).

Preferably, the content of the component (D) is 1 to 30 parts by mass based on 100 parts by mass of the component (A), and more preferably 10 to 25 parts by mass. The content of the component (D) of no less than 1 part by mass can improve film-forming ability and the content of no higher than 30 parts by mass can balance well with other components, in particular with the component (A).

### Solvent (E)

Preferably, the negative-type photosensitive resin composition is used as a solution in its use in which the components are dissolved in a solvent (E) (hereinafter, appropriately referred to as “component (E)”). The component (E) may be conventional solvents, without particular limitation. Examples thereof include γ-butyrolactone, ethyl lactate, propylene carbonate, propyleneglycol monomethylether acetate, methyl isobutylketone, butyl acetate, methyl amyl ketone, 2-heptanone, ethyl acetate and methyl ethyl ketone. Among these, γ-butyrolactone, ethyl lactate and propylene carbonate are preferably used in view of being incorporated into photosensitive resin layer upon reaction. These solvents may be used alone or as a mixture of two or more.

Preferably, the amount used of the component (E) is 5% to 30% by mass on the basis of solid concentration so as to form a photosensitive resin layer of 1 μm or more in film thickness by use of the negative-type photosensitive resin composition.

### Other Components

The negative-type photosensitive resin composition may contain a sensitizer such as naphthalene derivatives, anthracene derivatives and thioxanthone derivatives capable of forming crosslinking with the polyfunctional epoxy resin (A), in order to enhance sensitivity. The sensitizing function of the sensitizer can enhance the cross-link density of the polyfunctional epoxy resin to density the photosensitive resin layer itself, and the photosensitive resin layer can be made harder and less water-absorbable. Furthermore, the photosensitive resin layer can be made of higher Tg, harder and less heat-expandable due to having a plurality of aromatic rings.

The negative-type photosensitive resin composition may also contain an oxetane derivative or an epoxy derivative in view of enhancing flexibility of the photosensitive resin composition before curing, without degrading the properties of the photosensitive resin composition after curing. Furthermore, conventional miscible additives such as additive resins, plasticizers, stabilizers, colorants, leveling agents and coupling agents, for example, may be included in order to improve pattern performance as required.

### Positive-Type Photosensitive Resin Composition

It is preferred that the positive-type photosensitive resin composition contains a resin (F) to increase alkali-solubility by action of an acid, an acid generator (B) and an adhesion enhancer (C) as essential components, and also an optional alkali-soluble resin (G), etc.; it is preferred that these components are used in a solution condition through dissolving these components into a solvent (E). A resin, in which a hydroxyl group of an alkali-soluble resin is protected by an acid-dissociating solubility-inhibiting group to be made alkali-insoluble, is used as the resin (F) to increase alkali-solubility by action of an acid. When the resin (F) and the acid generator (B) are combined to use, the acid-dissociating solubility-inhibiting group dissociates by action of the acid generated at exposed portions. As a result, the exposed portions become alkali-soluble, and thus only the exposed portions are selectively removed upon development to produce a predetermined resin pattern.

### Resin (F) to Increase Alkali-Solubility by Action of Acid

The positive-type photosensitive resin composition contains the resin (F) to increase alkali-solubility by action of an acid (hereinafter, appropriately referred to as “component (F)”) as a base resin. At least one resin or mixed resins, selected from the group consisting of novolac resins (F1), polyhydroxystyrene resins (F2) and acrylic resins (F3), is used for the component (F).

### Novolac Resin (F1)

The resins expressed by the general formula (f1) below can be used for the novolac resins (F1).

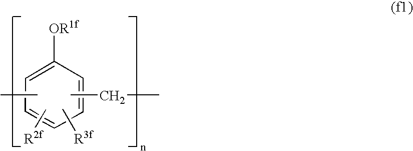

In the general formula (f1), R^{1f} represents an acid-dissociating solubility-inhibiting group; R^{2f} and R^{3f} each independently represent a hydrogen atom or an alkyl group having 1 to 6 carbon atoms; n is the number of repeating units.

It is also preferred that the acid-dissociating solubility-inhibiting group is a linear, branched or cyclic alkyl group having 1 to 6 carbon atoms expressed by the general formula (f2) or (f3) below, a tetrahydropyranyl group, a tetrafuranyl group, or a trialkylsilyl group.

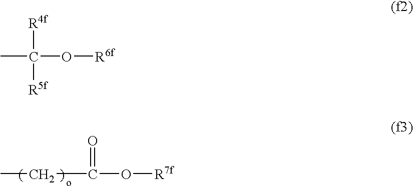

In the general formulas (f2) and (f3) above, R^{4f} and R^{5f} each independently represent a hydrogen atom or a linear or branched alkyl group having 1 to 6 carbon atoms; R^{6f} represents a linear, branched or cyclic alkyl group having 1 to 10 carbon atoms; R^{7f} represents a linear, branched or cyclic alkyl group having 1 to 6 carbon atoms; and o is 0 or 1.

Examples of the linear or branched alkyl group having 1 to 6 carbon atoms include a methyl group, ethyl group, propyl group, isopropyl group, n-butyl group, isobutyl group, tert-butyl group, pentyl group, isopentyl group and neopentyl group; examples of the cyclic alkyl group include a cyclopentyl group and cyclohexyl group.

Specific examples of the acid-dissociating solubility-inhibiting group expressed by the general formula (f2) are a methoxyethyl group, ethoxyethyl group, n-propoxyethyl group, iso-propoxyethyl group, n-butoxyethyl group, isobutoxyethyl group, tert-butoxyethyl group, cyclohexyloxyethyl group, methoxypropyl group, ethoxypropyl group, 1-methoxy-1-methyl-ethyl group and 1-ethoxy-1-methyl-ethyl group; and specific examples of the acid-dissociating solubility-inhibiting group expressed by the general formula (f3) are a tert-butoxycarbonyl group and tert-butoxycarbonylmethyl group. Examples of the trialkylsilyl group include a trimethylsilyl group and tri-tert-butyldimethylsilyl group in which each alkyl group has 1 to 6 carbon atoms.

### Polyhydroxystyrene Resin (F2)

The resins expressed by the general formula (f4) below can be used for the polyhydroxystyrene resin (F2).

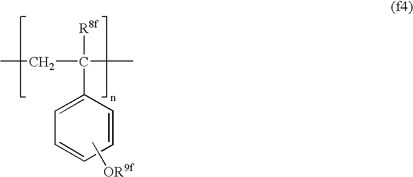

In the general formula (f4) above, R^{8f} represents a hydrogen atom or an alkyl group having 1 to 6 carbon atoms; R^{9f} represents an acid-dissociating solubility-inhibiting group; n is the number of repeating units.

Examples of the linear or branched alkyl group having 1 to 6 carbon atoms include a methyl group, ethyl group, propyl group, isopropyl group, n-butyl group, isobutyl group, tert-butyl group, pentyl group, isopentyl group, and neopentyl group; examples of the cyclic alkyl group include a cyclopentyl group and cyclohexyl group.

The acid-dissociating solubility-inhibiting group expressed by R^{9f} above may be similar to the acid-dissociating solubility-inhibiting groups exemplified in terms of the general formulas (f2) and (f3).

Furthermore, the polyhydroxystyrene resin (F2) may contain another polymerizable compound as a structural unit in order to moderately control physical or chemical properties. The polymerizable compound is exemplified by conventional radical polymerizable compounds and anion polymerizable compounds. Examples thereof include monocarboxylic acids such as acrylic acid, methacrylic acid and crotonic acid; dicarboxylic acids such as maleic acid, fumaric acid and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid and 2-methacryloyloxyethyl hexahydrophthalic acid; (meth)acrylic acid alkyl esters such as methyl(meth)acrylate, ethyl(meth)acrylate and butyl(meth)acrylate; (meth)acrylic acid hydroxyalkyl esters such as 2-hydroxyethyl(meth)acrylate and 2-hydroxypropyl (meth)acrylate; (meth)acrylic acid aryl esters such as phenyl(meth)acrylate and benzyl (meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide.

### Acrylic Resin (F3)

The resins expressed by the general formulas (f5) to (f7) below can be used for the acrylic resin (F3).

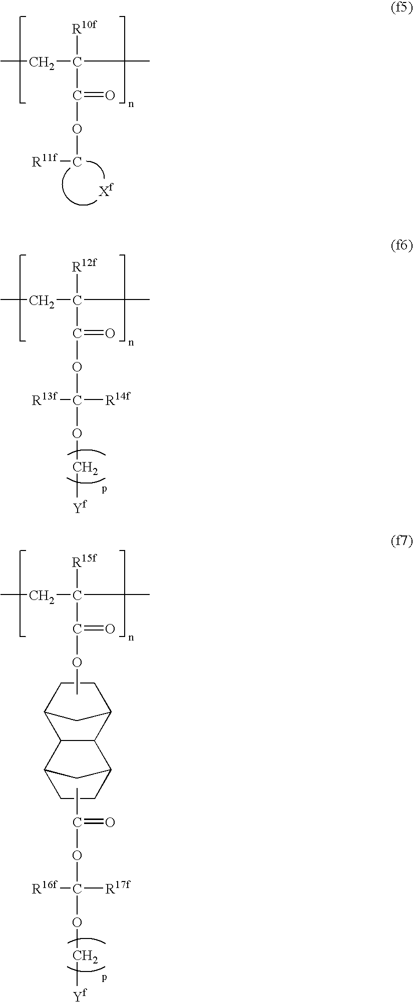

In the general formulas (f5) to (f7), R^{10f} to R^{17f} each independently represent a hydrogen atom, a linear or branched alkyl group having 1 to 6 carbon atoms, a fluorine atom, or a linear or branched fluorinated alkyl group having 1 to 6 carbon atoms (in which, R^{11b} is not a hydrogen atom); X^{f} and the neighboring carbon atoms form a hydrocarbon ring having 5 to 20 carbon atoms; Y^{f} represents an alicyclic or alkyl group that may have a substituent; n is the number of repeating units; p is an integer of 0 to 4; and q is 0 or 1.

Examples of the linear or branched alkyl group having 1 to 6 carbon atoms include a methyl group, ethyl group, propyl group, isopropyl group, n-butyl group, isobutyl group, tert-butyl group, pentyl group, isopentyl group and neopentyl group; examples of the cyclic alkyl group include a cyclopentyl group and cyclohexyl group. The fluorinated alkyl group refers to the abovementioned alkyl groups of which the hydrogen atoms are partially or entirely substituted with fluorine atoms.

Preferably, R^{11f} is a linear or branched alkyl group having 2 to 4 carbon atoms in view of higher contrast, proper resolution and focus depth width, etc.; preferably, R^{13f}, R^{14f}, R^{16f} and R^{17f} are each a hydrogen atom or a methyl group.

The abovementioned X^{f} and the neighboring carbon atoms form an alicyclic group having 5 to 20 carbon atoms. Specific examples of the alicyclic group are the groups of monocycloalkanes and polycycloalkanes such as bicycloalkanes, tricycloalkanes and tetracycloalkanes from which at least one hydrogen atom is removed. Specific examples thereof are monocycloalkanes such as cyclopentane, cyclohexane, cycloheptane and cyclooctane and polycycloalkanes such as adamantane, norbornane, isobornane, tricyclodecane and tetracyclododecane from which at least one hydrogen atom is removed. Particularly preferable are cyclohexane and adamantane from which at least one hydrogen atom is removed (that may further have a substituent).

When the alicyclic group of the abovementioned X^{f} has a substituent on the ring skeleton, the substituent is exemplified by polar groups such as a hydroxide group, carboxyl group, cyano group and oxygen atom (═O) and linear or branched lower alkyl groups having 1 to 4 carbon atoms. The polar group is preferably an oxygen atom (═O) in particular.

The abovementioned Y^{f} is an alicyclic group or an alkyl group; examples thereof are monocycloalkanes and polycycloalkanes such as bicycloalkanes, tricycloalkanes and tetracycloalkanes from which at least one hydrogen atom is removed. Specific examples thereof are monocycloalkanes such as cyclopentane, cyclohexane, cycloheptane and cyclooctane and polycycloalkanes such as adamantane, norbornane, isobornane, tricyclodecane and tetracyclododecane from which at least one hydrogen atom is removed. Particularly preferable is adamantane from which at least hydrogen atom is removed (that may further have a substituent).

When the alicyclic group of the abovementioned Y^{f} has a substituent on the ring skeleton, the substituent is exemplified by polar groups such as a hydroxide group, carboxyl group, cyano group and oxygen atom (═O), and linear or branched lower alkyl groups having 1 to 4 carbon atoms. The polar group is preferably an oxygen atom (═O) in particular.

When Y^{f} is an alkyl group, it is preferably a linear or branched alkyl group having 1 to 20 carbon atoms, and more preferably 6 to 15 carbon atoms. Preferably, the alkyl group is an alkoxyalkyl group in particular; examples of the alkoxyalkyl group include a 1-methoxyethyl group, 1-ethoxyethyl group, 1-n-propoxyethyl group, 1-isopropoxyethyl group, 1-n-butoxyethyl group, 1-isobutoxyethyl group, 1-tert-butoxyethyl group, 1-methoxypropyl group, 1-ethoxypropyl group, 1-methoxy-1-methylethyl group and 1-ethoxy-1-methylethyl group.

Preferable specific examples of the acrylic resin expressed by the general formula (f5) are those expressed by the general formulas (f5-1) to (f5-3) below.

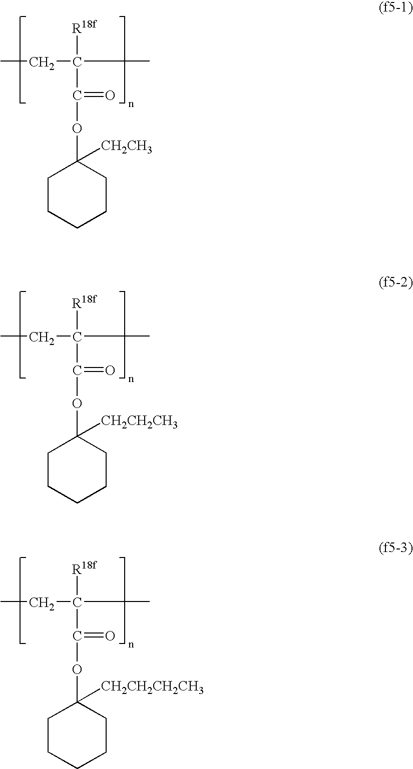

R^{18f} in the general formulas (f5-1) to (f5-3) above represents a hydrogen atom or a methyl group; n is the number of repeating units.

Preferable specific examples of the acrylic resin expressed by the general formula (f6) are those expressed by the general formulas (f6-1) to (f6-28) below.

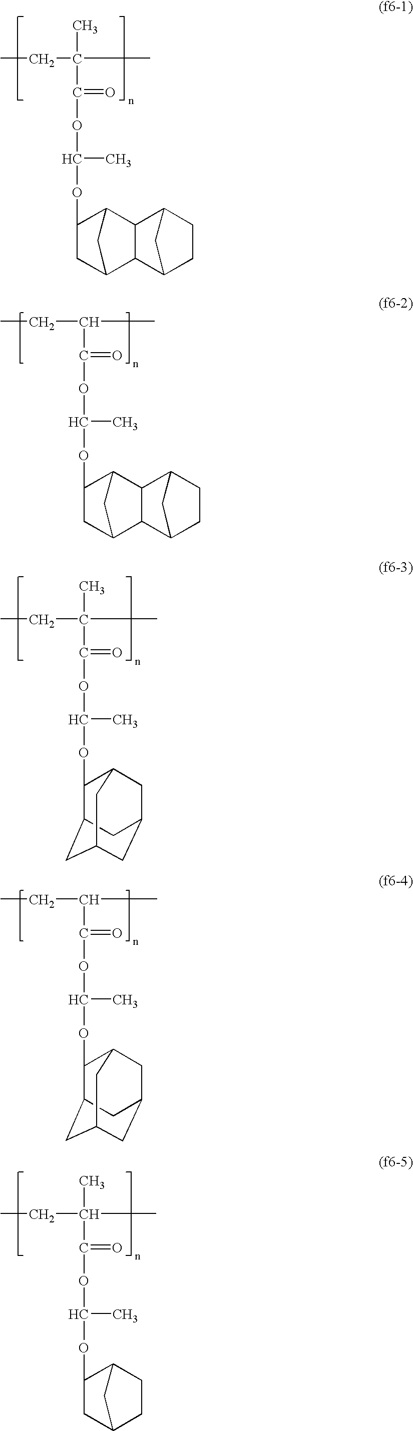

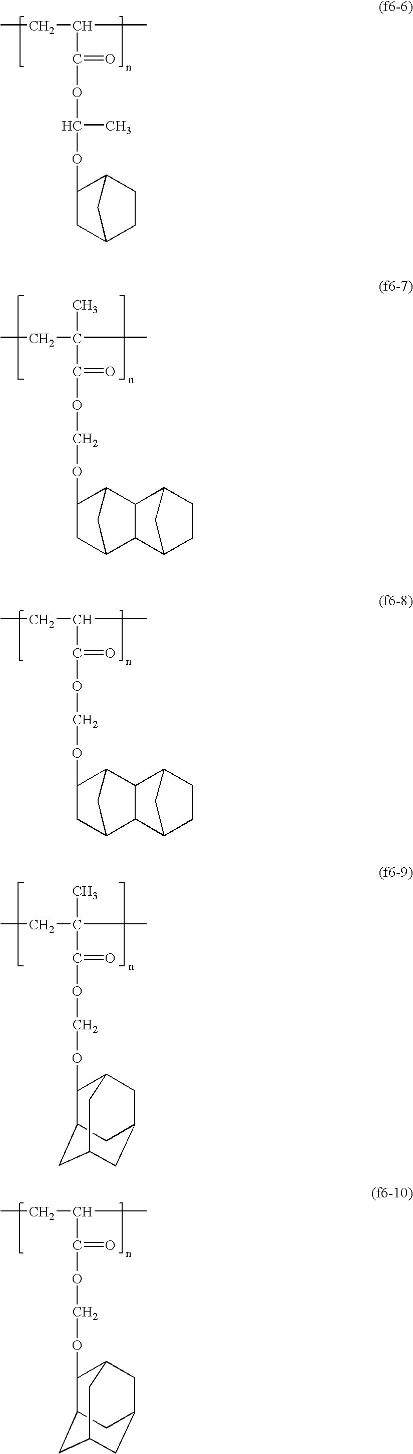

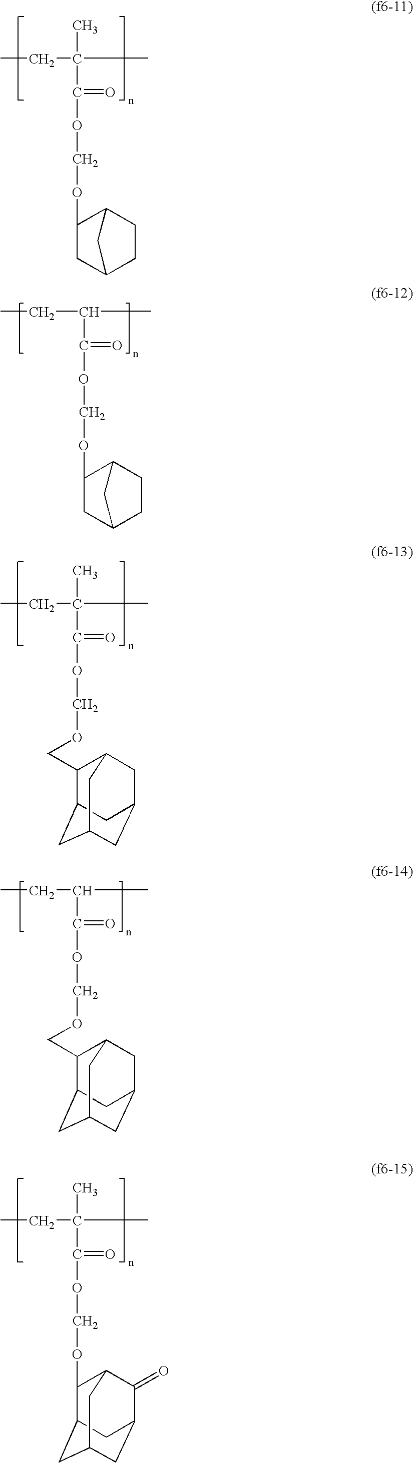

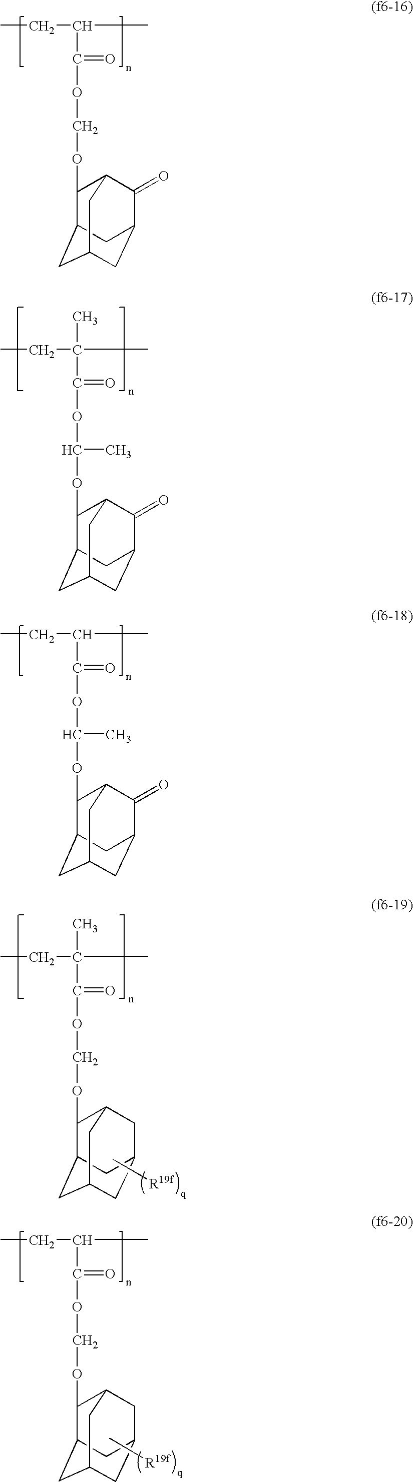

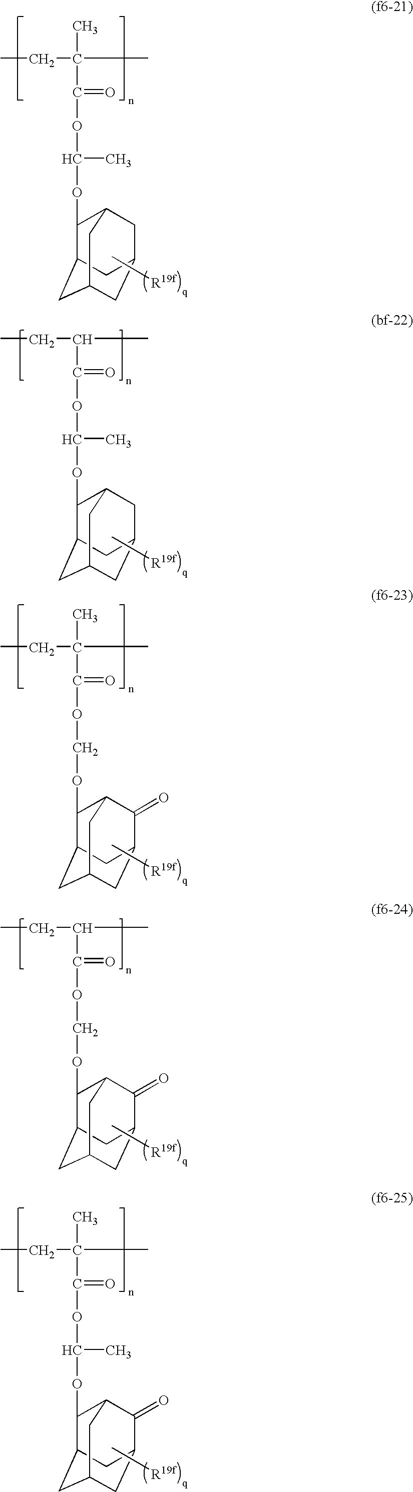

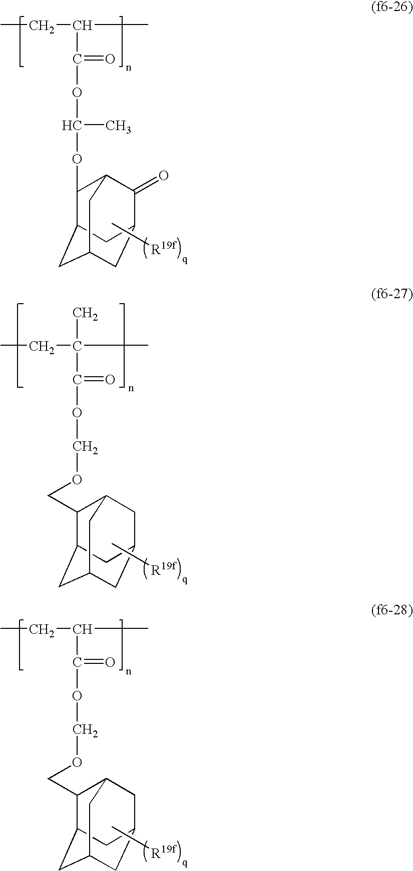

Preferable specific examples of the acrylic resin expressed by the general formula (f7) are those expressed by the general formulas (f7-1) to (f7-22) below.

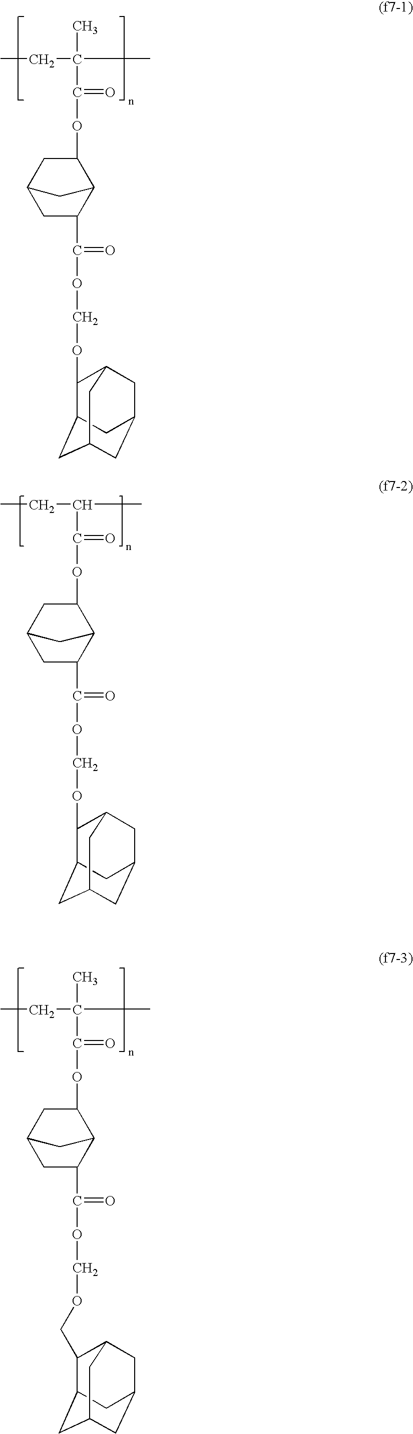

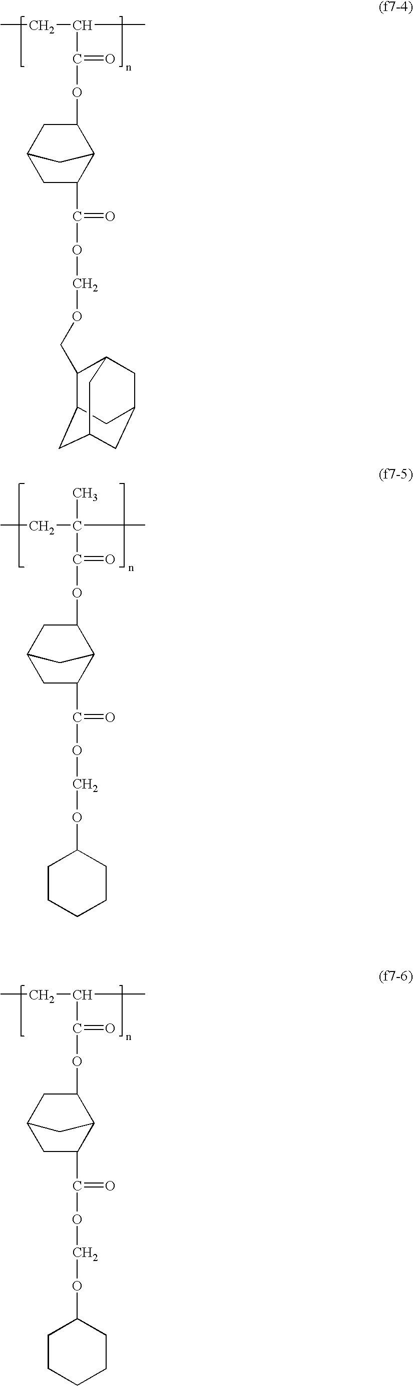

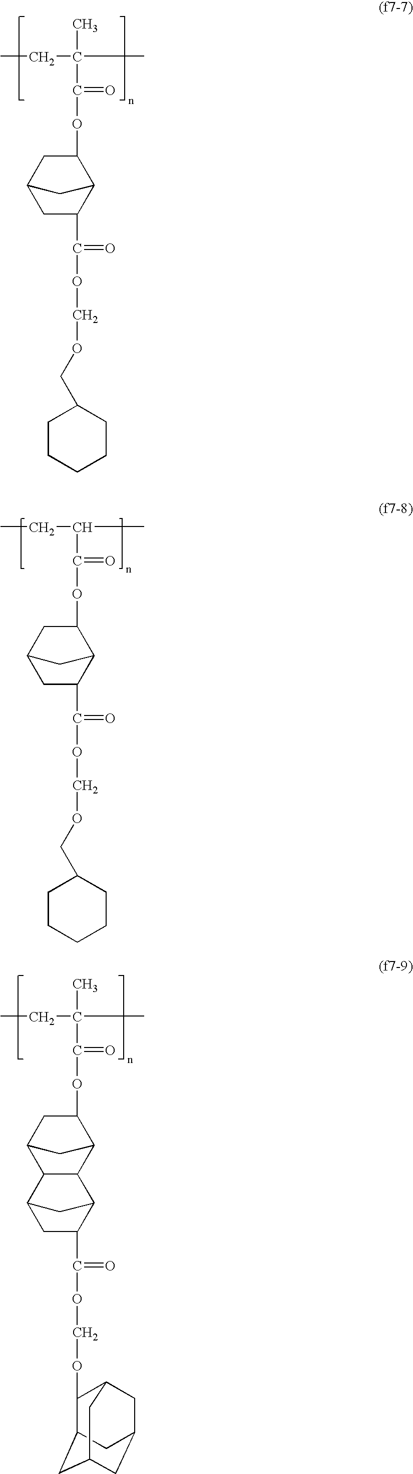

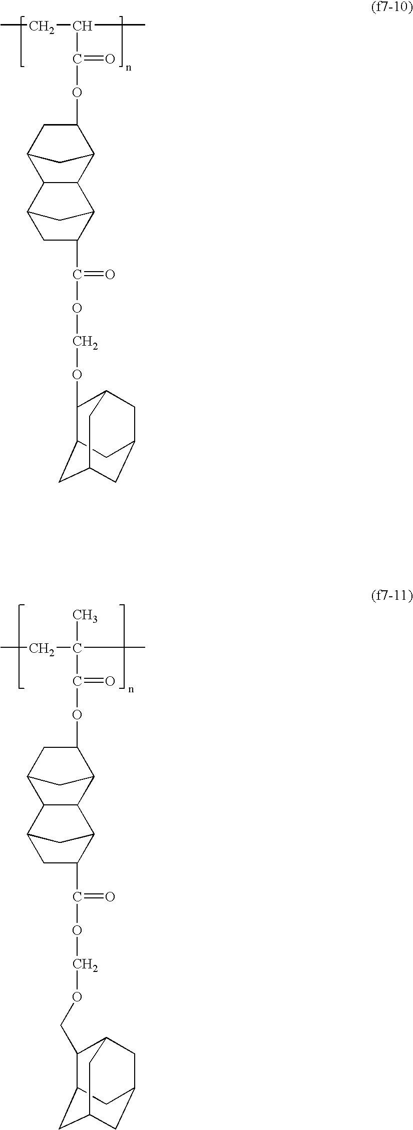

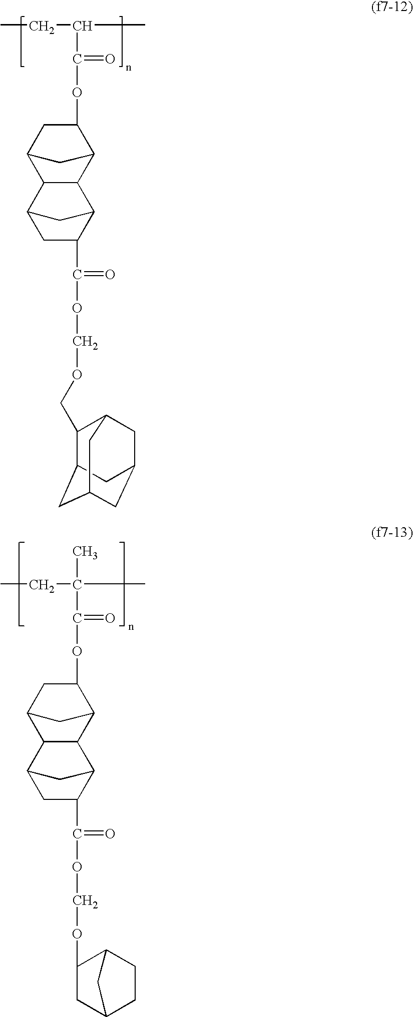

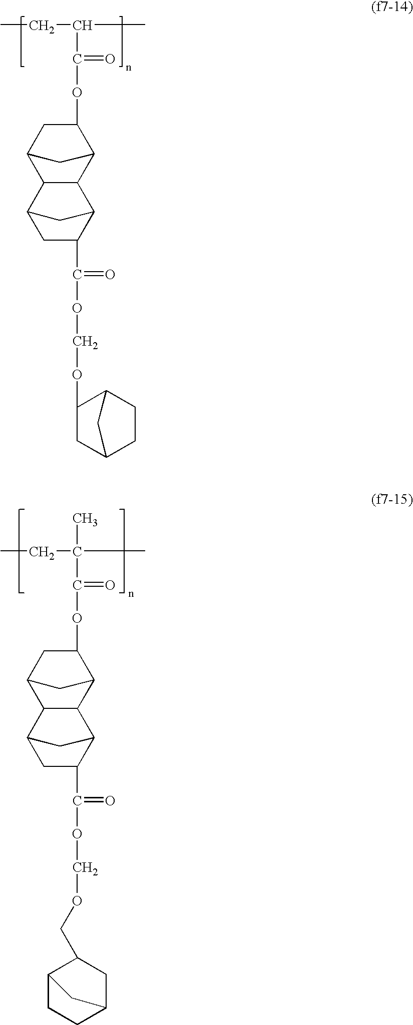

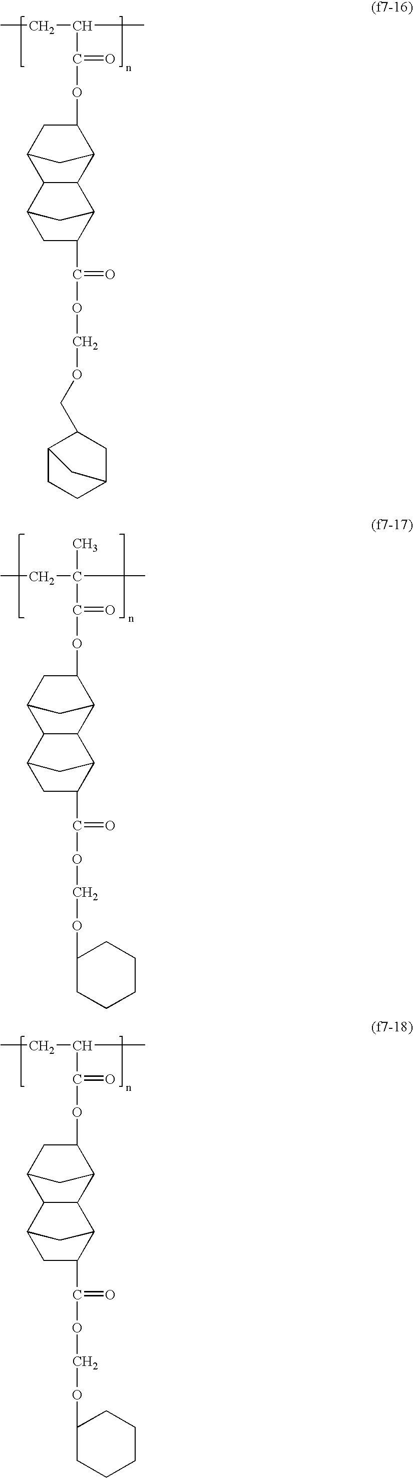

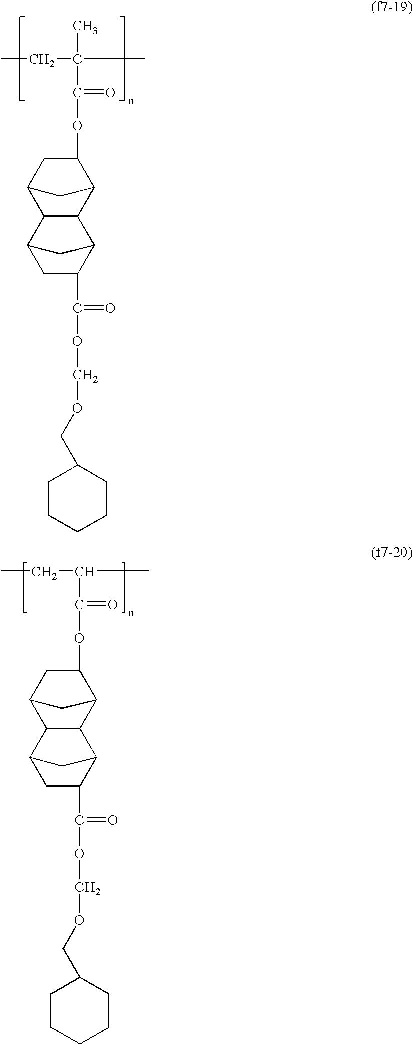

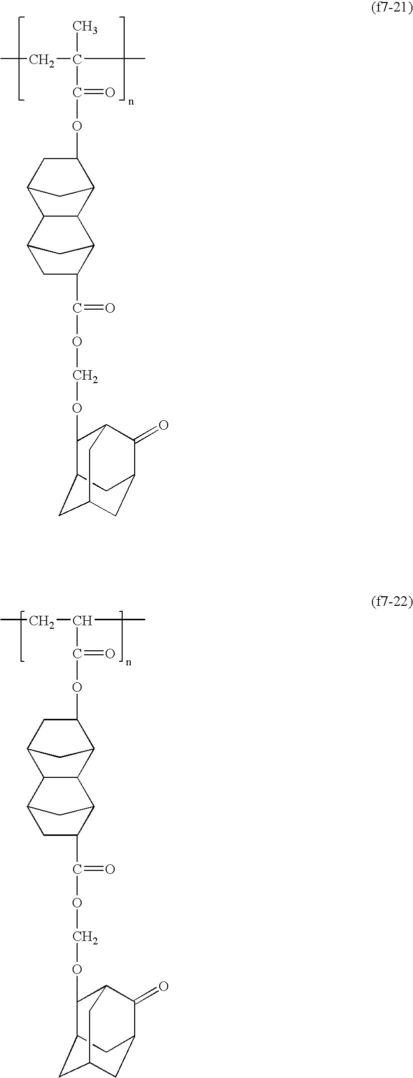

It is also preferred that the acrylic resin (F3) includes a copolymer containing a structural unit derived from a polymerizable compound having an ether bond in addition to the structural unit expressed by the general formulas (f5) to (f7).

The structural unit is such a structural unit that is derived from a polymerizable compound having an ether bond. Examples of the polymerizable compound having an ether bond are radical polymerizable compounds like (meth)acrylic acid derivatives, having an ether bond and an ester bond, where 2-methoxyethyl(meth)acrylate, 2-ethoxyethyl (meth)acrylate, methoxytriethylene glycol (meth)acrylate, 3-methoxybutyl(meth)acrylate, ethylcarbitol(meth)acrylate, phenoxypolyethylene glycol(meth)acrylate, methoxypolypropylene glycol(meth)acrylate and tetrahydrofurfuryl(meth)acrylate; 2-methoxyethyl(meth)acrylate, 2-ethoxyethyl(meth)acrylate and methoxytriethylene glycol(meth)acrylate are preferable. These compounds may be used alone or in combinations of two or more.

Furthermore, the acrylic resin (F3) may contain another polymerizable compound as a structural unit in order to moderately control physical or chemical properties. The polymerizable compound is exemplified by conventional radical polymerizable compounds and anion polymerizable compounds. Examples thereof include monocarboxylic acids such as acrylic acid, methacrylic acid and crotonic acid; dicarboxylic acids such as maleic acid, fumaric acid and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid and 2-methacryloyloxyethyl hexahydrophthalic acid; (meth)acrylic acid alkyl esters such as methyl(meth)acrylate, ethyl(meth)acrylate and butyl(meth)acrylate; (meth)acrylic acid hydroxyalkyl esters such as 2-hydroxyethyl(meth)acrylate and 2-hydroxypropyl(meth)acrylate; (meth)acrylic acid aryl esters such as phenyl(meth)acrylate and benzyl(meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide.

Among the above, the acrylic resin (F3) is preferably used.

It is preferred in particular that the acrylic resin (F3) is a copolymer having a structural unit expressed by the general formula (f7) above, a structural unit derived from a polymerizable compound having an ether bond, a unit of (meth)acrylic acid and a structural unit of (meth)acrylic acid alkylesters.

The copolymer is preferably a copolymer expressed by the general formula (f8) below.

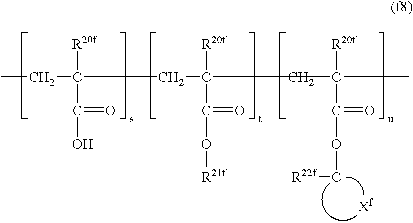

In the general formula (f8) above, R^{20f} represents a hydrogen atom or a methyl group; R^{21f} represents a linear or branched alkyl or alkoxyalkyl group having 1 to 6 carbon atoms; R^{22f} represents a linear or branched alkyl group having 2 to 4 carbon atoms; and X^{f} is the same as described above.

In regards to the copolymers expressed by the general formula (f8), s, t and u are each mass ratios, s is 1% to 30% by mass, t is 20% to 70% by mass and u is 20% to 70% by mass.

The mass average molecular mass of the component (F) is preferably 10,000 to 600,000, more preferably 50,000 to 600,000, and still more preferably 30,000 to 550,000. Consequently, the photosensitive resin layer can maintain sufficient strength without degrading peel properties with substrates, and also swelling of profiles when plating and generation of cracks can be prevented.

It is also preferred that the component (F) has a dispersivity of no less than 1.05. The dispersivity indicates a value of a mass average molecular mass divided by a number average molecular mass. The dispersivity in the range described above can avoid problems with respect to stress resistance on intended plating or possible swelling of metal layers resulting from plating treatment.

Preferably, the content of the component (F) is 5% to 60% by mass based on the solid content of the positive-type photosensitive resin composition.

### Acid Generator (B)

The acid generator (B) may be similar to the acid generator in the negative-type photosensitive resin composition. Preferably, the content of the component (B) is 0.05% to 5% by mass based on the solid content of the positive-type photosensitive resin composition. Content of the component (B) of no less than 0.05% by mass may result in sufficient sensitivity, and content of no more than 5% by mass tends to enhance solubility in a solvent to provide a uniform solution and to improve preservation stability.

### Adhesion Enhancer (C)

The adhesion enhancer (C) may be similar to the adhesion enhancer in the negative-type photosensitive resin composition. The content of the component (C) is preferably 0.01 to 20 parts by mass based on 100 parts by mass of the component (F), and more preferably 0.1 to 10 parts by mass. However, when the component (C) has an amino group or a nitro group, these functional groups deactivate the acid generated from the component (B); it is, therefore, preferred that the content of component (C) is 0.01 to 20 parts by mass based on 100 parts by mass of the component (F), and more preferably 0.01 to 2 parts by mass. This can enhance adhesion with substrates when forming a film.

### Alkali-Soluble Resin (G)

The positive-type resin composition may contain an alkali-soluble resin (G) (hereinafter, appropriately referred to as “component (G)”) in order to improve crack resistance. Preferably, the component (G) is at least one selected from the group consisting of novolac resins (G1), polyhydroxystyrene resins (G2), acrylic resins (G3) and polyvinyl resins (G4).

### Novolac Resins (G1)

Preferably, the mass average molecular mass of the novolac resins (G1) is 1,000 to 50,000.

The novolac resins (G1) may be prepared by addition condensation between aromatic compounds having a phenolic hydroxide group (hereinafter, simply referred to as “phenols”) and aldehydes in the presence of an acid catalyst. Examples of the useful phenols include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, p-phenylphenol, resorcinol, hydroquinone, hydroquinone monomethyl ether, pyrogallol, fluoroglycinol, hydroxydiphenyl, bisphenol A, gallic acid, gallic acid ester, α-naphthol and β-naphthol.

Examples of the aldehydes include formaldehyde, furfural, benzaldehyde, nitrobenzaldehyde and acetoaldehyde. The catalyst used in the addition condensation reaction, which is not specifically limited, is exemplified by hydrochloric acid, nitric acid, sulfuric acid, formic acid, oxalic acid and acetic acid in regards to acid catalyst.

The flexibility of the resins can be enhanced still more when o-cresol is used, a hydrogen atom of a hydroxide group in the resins is substituted with other substituents, or bulky aldehydes are used.

### Polyhydroxystyrene Resin (G2)

Preferably, the mass average molecular mass of the polyhydroxystyrene resin (G2) is 1,000 to 50,000.

The hydroxystyrene compound to constitute the polyhydroxystyrene resin (G2) is exemplified by p-hydroxystyrene, α-methylhydroxystyrene and α-ethylhydroxystyrene. It is also preferred that the polyhydroxystyrene resin (G2) is a copolymer with a styrene resin; and the styrene compound to constitute the styrene resin is exemplified by styrene, chlorostyrene, chloromethylstyrene, vinyltoluene and α-methylstyrene.

### Acrylic Resin (G3)

Preferably, the mass average molecular mass of the acrylic resin (G3) is 50,000 to 800,000.

Preferably, the acrylic resin (G3) contains a monomer derived from a polymerizable compound having an ether bond and a monomer derived from a polymerizable compound having a carboxyl group.

Examples of the polymerizable compound having an ether bond include (meth)acrylic acid derivatives, having an ether bond and an ester bond, such as 2-methoxyethyl(meth)acrylate, methoxytriethylene glycol(meth)acrylate, 3-methoxybutyl(meth)acrylate, ethylcarbitol(meth)acrylate, phenoxypolyethylene glycol(meth)acrylate, methoxypolypropylene glycol(meth)acrylate and tetrahydrofurfuryl(meth)acrylate; and 2-methoxyethyl acrylate and methoxytriethylene glycol acrylate are preferable. These compounds may be used alone or in combinations of two or more.

Examples of the polymerizable compound having a carboxyl group include monocarboxylic acids such as acrylic acid, methacrylic acid and crotonic acid; dicarboxylic acids such as maleic acid, fumaric acid and itaconic acid; compounds having a carboxyl group and an ester bond such as 2-methacryloyloxyethyl succinic acid, 2-methacryloyloxyethyl maleic acid, 2-methaeryloyloxyethyl phthalic acid and 2-methacryloyloxyethylhexahydro phthalic acid; and acrylic acid and methacrylic acid are preferable. These compounds may be used alone or in combinations of two or more.

### Polyvinyl Resin (G4)

Preferably, the mass average molecular mass of the polyvinyl resin (G4) is 10,000 to 200,000, and more preferably 50,000 to 100,000.

The polyvinyl resin (G4) is a poly(vinyl lower alkyl ether) and includes a (co)polymer obtained by polymerizing one or a mixture of two or more vinyl lower alkyl ethers expressed by the general formula (g1) below.

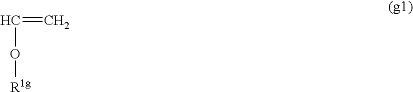

In the general formula (g1) above, R^{1g} represents a linear or branched alkyl group having 1 to 6 carbon atoms.

The polyvinyl resin (G4) is a polymer prepared from vinyl compounds; specifically, the polyvinyl resin is exemplified by polyvinyl chloride, polystyrene, polyhydroxystyrene, polyvinyl acetate, polyvinyl benzoate, polyvinyl methyl ether, polyvinyl ethyl ether, polyvinyl alcohol, polyvinyl pyrrolidone, polyvinyl phenol and copolymers thereof. Among these, polyvinyl methyl ether is preferable in view of lower glass transition temperatures.

The content of the component (G) is preferably 5 to 95 parts by mass based on 100 parts by mass of the component (F), and more preferably 10 to 90 parts by mass. Content of the component (G) of no less than 5 parts by mass tends to improve crack resistance and content of no more than 95 parts by mass tends to prevent film decrease at development.

### Solvent (E)

Preferably, the positive-type photosensitive resin composition is used as a solution in its use in which the components are dissolved in a solvent (E). The component (E) may be conventional solvents, without particular limitation. Examples thereof include ketones such as acetone, methyl ethyl ketone, cyclohexanone, methyl isoamyl ketone and 2-heptanone; polyhydric alcohols and derivatives thereof, like monomethyl ethers, monoethyl ethers, monopropyl ethers, monobutyl ethers or monophenyl ethers, such as ethylene glycol, ethylene glycol monoacetate, diethylene glycol, diethylene glycol monoacetate, propylene glycol, propylene glycol monoacetate, dipropylene glycol and dipropylene glycol monoacetate; cyclic ethers such as dioxane; esters such as ethyl formate, methyl lactate, ethyl lactate, methyl acetate, ethyl acetate, butyl acetate, methyl pyruvate, methyl acetoacetate, ethyl acetoacetate, methyl pyruvate, ethylethoxy acetate, methyl methoxypropionate, ethyl ethoxypropionate, methyl 2-hydroxypropionate, ethyl 2-hydroxypropionate, ethyl 2-hydroxy-2-methylpropionate, methyl 2-hydroxy-3-methylbutanate, 3-methoxybutyl acetate and 3-methyl-3-methoxybutyl acetate; and aromatic hydrocarbons such as toluene and xylene. These solvents may be used alone or in combinations of two or more.

Preferably, the amount used of the component (E) is 5% to 30% by mass on the basis of solid concentration so as to form the photosensitive resin layer of at least 1 μm in film thickness by use of the positive-type photosensitive resin composition.

### Other Components

The positive-type photosensitive resin composition may be optionally added and included with miscible additives in common use such as additive resins, sensitizers, acid-diffusion controllers, adhesion auxiliaries, stabilizers, colorants and leveling agents in order to improve the performance of resist films.

### Method for Forming a Pattern

When a resin pattern is formed, firstly, a photosensitive resin layer of the photosensitive resin composition is formed on a substrate. The substrate may be conventional without particular limitation in which, for example, substrates for electronic parts or those on which a predetermined pattern is formed can be exemplified. The substrate may be metal substrates such as of silicon, silicon nitride, titanium, tantalum, palladium, titanium/tungsten, platinum, gold, copper, chromium, iron, nickel and aluminum or glass substrates. The photosensitive resin composition of the present invention can form fine resin patterns, even on gold or copper substrates in particular. Copper, solder, chromium, aluminum, nickel, gold, etc., for example, may be used for the material of the wiring patterns.

Specifically, the photosensitive resin composition is coated on a predetermined substrate, and then the solvent is removed through heating to form an intended photosensitive resin layer. Spin coating processes, slit coating processes, roll coating processes, screen coating processes, applicator processes, etc. can be employed for the coating method on the substrate. The heating conditions depend on the species of components in the composition, compounding ratios, coated film thicknesses, etc., and usually, the heating is carried out in the range of 70° C. to 120° C., and preferably at from 80° C. to 100° C. for 5 to 20 minutes. The film thickness of the photosensitive resin layer is within a range of 5 to 150 μm, preferably 10 to 120 μm, and more preferably 10 to 100 μm.

Then, the resulting photosensitive resin layer is selectively irradiated (exposed) with an active light ray or radiation, for example, UV-ray or visible light having a wavelength of 200 to 500 nm through a mask of a predetermined pattern.

The active light ray indicates a light ray to activate the acid generator in order to generate an acid. Low pressure mercury lamps, high pressure mercury lamps, super high pressure mercury lamps, metal halide lamps, argon gas lasers, etc. can be used for the light source of the radiation. The radiation indicates UV-rays, visible lights, far-UV rays, X rays, electron beams, ion beams, etc. The radiation dose depends on the species of components in the composition, blending quantities, thicknesses of coated compounding ratios, coated film thicknesses, etc. and is 100 to 10,000 mJ/cm² in cases of super high pressure mercury lamps, for example.

Then, diffusion of the acid is promoted through heating by conventional processes, followed by dissolving and eliminating unnecessary portions using a developer to obtain a resin pattern with a predetermined shape.

Thereafter, in a case where connecting terminals such as metal posts and bumps are to be formed, conductors such as of metals are embedded into concave sites (portions being removed by developer) of the resulting resin pattern by way of plating, for example. The plating process can be selected from various conventional processes without particular restriction. Solder plating, copper plating, gold plating and nickel plating liquids are preferably used for the plating liquid, in particular. Finally, the remaining resin patterns are eliminated using a stripping liquid, etc. in accordance with a common process.

### EXAMPLES

Examples of the present invention are explained hereinafter; however, the present invention should not be limited to the examples.

### Examples 1 to 3, Comparative Example 1

Negative-type photosensitive resin compositions were prepared by compounding a polyfunctional epoxy resin, an acid generator, adhesion enhancers, a solvent and a sensitizer in accordance with the formulations (unit: part by mass) described in Table 1.

These photosensitive resin compositions were each coated on a gold substrate of 5 inches using a spin coater, and then dried to obtain a photosensitive resin layer having a film thickness of 30 μm. The photosensitive resin layer was prebaked at 60° C. for 5 minutes and at 90° C. for 10 minutes. After the prebaking, pattern exposure (soft contact, GHI ray) was carried out using PLA-501F (contact aligner, by Canon Inc.), and post-exposure baking (PEB) was carried out at 90° C. for 10 minutes using a hot plate. Then, developing treatment was carried out for 8 minutes by an immersion process using propylene glycol monomethyl ether acetate (PGMEA). Next, the developed resin pattern was post-baked together with the substrate at 200° C. for 1 hour using an oven to obtain a resin pattern hardened on the substrate.

### Evaluation

In regards to evaluation of fine line adhesion, the width of the most closely-attached fine pattern was measured and evaluated for the pattern formed at an exposure of 600 mJ/cm². The evaluation results are shown in Table 1.

TABLE 1

| | Component | Ex. 1 | Ex. 2 | Ex. 3 | Com. Ex. 1 |
|---|---|---|---|---|---|
| Polyfunctional epoxy | A | 100 | 100 | 100 | 100 |
| resin | | | | | |
| Acid generator | B | 3 | 3 | 3 | 5 |
| Adhesion enhancer | C-1 | 1 | — | — | — |
| | C-2 | — | 1 | — | — |
| | C-3 | — | — | 1 | — |
| | C-4 | — | — | — | 5 |
| Solvent | E | 50 | 50 | 50 | 50 |
| Sensitizer | S | 1 | 1 | 1 | 1 |
| Exposure (mJ/cm²) | | 600 | 600 | 600 | 600 |
| Fine line adhesion | | 4 | 4 | 4 | >80 |
| (μm) | | | | | |

(A): polyfunctional bisphenol A novolac-type epoxy resin: jER157S70 (by Japan Epoxy Resin Co., trade name)
(B): acid generator: diphenyl[4-(phenylthio)phenyl]sulfonium hexafluoroantimonate
(C-1): adhesion enhancer: 3,3′-diaminodiphenylsulfone
(C-2): adhesion enhancer: 4,4′-diaminodiphenylsulfone
(C-3): adhesion enhancer: diphenylsulfone
(C-4): adhesion enhancer (silane coupling agent): KBM-403 (by Shin-Etsu Silicone Co., trade name)
(E): solvent: γ-butyrolactone
(S): sensitizer: α-naphthol

Table 1 demonstrates that the photosensitive resin compositions of Examples 1 to 3 containing diphenyl sulfone or a derivative thereof as an adhesion enhancer, where the adhesion enhancer is compounded in an amount of 1 part by mass based on 100 parts by mass of the polyfunctional epoxy resin, and each led to a fine resin pattern of 4 μm on the gold substrate. On the other hand, the photosensitive resin composition of Comparative Example 1 containing a silane coupling agent as an adhesion enhancer resulted in that a resin pattern of 80 μm did not adhere on the gold substrate, even when the adhesion enhancer being compounded in an amount of 5 parts by mass based on 100 parts by mass of the polyfunctional epoxy resin.

What is claimed is:

1. A photosensitive resin composition, comprising diphenyl sulfone or a derivative thereof as an adhesion enhancer.

2. The photosensitive resin composition according to claim 1, wherein the adhesion enhancer comprises a diphenyl sulfone derivative obtained by substituting at least one hydrogen atom of the diphenyl sulfone with a group selected from the group consisting of an amino group, a nitro group, a hydroxyl group, a carboxyl group, a fluorine atom, a chlorine atom and an acid anhydride.

3. The photosensitive resin composition according to claim 1, wherein the adhesion enhancer comprises a diphenyl sulfone derivative derived by substituting hydrogen atoms at no less than one of 3,3′ positions and 4,4′ positions of the diphenyl sulfone with at least one group selected from the group consisting of an amino group, a nitro group, a hydroxyl group, a carboxyl group, a fluorine atom, a chlorine atom and an acid anhydride.

4. The photosensitive resin composition according to claim 1, further comprising a polyfunctional epoxy resin and an acid generator for generating an acid upon irradiation with an active light ray or radiation.

5. The photosensitive resin composition according to claim 4, wherein the composition comprises from 0.01 to 20 parts by mass of the adhesion enhancer based on 100 parts by mass of the polyfunctional epoxy resin.

6. The photosensitive resin composition according to claim 1, wherein said composition forms a photosensitive resin layer on a gold substrate.

7. A method for forming a pattern, comprising:
coating and drying a photosensitive resin composition according to claim 1 on a substrate to form a coating;
exposing the coating with a predetermined pattern; and developing to prepare a resin pattern with a predetermined shape.
